(19) United States
(12) Patent Application Publication
(10) Pub. No.: US 2004/0232523 A1
(43) Pub. Date: Nov. 25, 2004

(54) Electronically tunable RF chip packages

(76) Inventors: Khosro Shamsaifar, Ellicott City, MD (US); Nicolaas du Toit, Columbia, MD (US); Louise C. Sengupta, Ellicott City, MD (US)

Correspondence Address: James S. Finn, c/o William Tucker, 8650 Southwestern Blvd. #2825, Dallas, TX, 75206-2688, US

(21) Appl. No.: 10/837,096

(22) Filed: Apr. 30, 2004

Related U.S. Application Data
(60) Provisional application No. 60/466,631, filed on Apr. 30, 2003.

(51) Int. Cl. H01L 29/93

(52) U.S. Cl. 257/602

(57) ABSTRACT

A packaged semiconductor chip comprising a first semiconductor chip 120 having an upwardly-facing front face 145, a downwardly-facing rear face 155, edges 160 bounding the faces and contacts 150 exposed at the front surface 145, the first semiconductor chip 120 including active components. The packaged semiconductor chip 100 further includes a connecting element 105 which may include passive components, the connecting element 105 may be electrically connected to at least some of the contacts 150, the connecting element 105 overlying the front face 145 of the first chip 120 and projecting outwardly beyond the edges 160 of the first chip 120. The packaged semiconductor chip 100 also comprises a chip carrier 130 disposed below the rear surface 155 of the first chip 120, the chip carrier 130 having a bottom surface 132 facing downwardly away from the chip 120 and having a plurality of terminals 134 and 136 exposed at the bottom surface, at least some of the terminals 134 and 136 being electrically connected to at least some of the contacts 150 of the first chip through the connecting element. A voltage tunable capacitor 125 may be electrically connected to the connecting element and the first chip 120 may include active semiconductor components.

### CROSS REFERENCE TO A RELATED APPLICATION

This application claims the benefit of U.S. Provisional Application Ser. No. 60/466,631, filed Apr. 30, 2003, entitled, “Electronically Tunable RF Chip Packages.”

### BACKGROUND OF INVENTION

Electrically tunable microwave devices have found a wide range of applications in microwave systems. Compared to mechanically and magnetically tunable RF components, electronically tunable devices have an advantage of a fast tuning capability over wide frequency band applications. Because of this advantage, they may be used in applications such as LMDS (local multipoint distribution service), cellular, GSM, PCS, UMTS, frequency hopping, satellite communication, and radar systems. Electronically tunable devices can be divided into three types: Voltage-controlled tunable dielectric capacitor based tunable devices; Semiconductor varactor based tunable filters; and MEMS varactors Compared to semiconductor varactor based tunable devices, tunable dielectric capacitor based tunable devices have the merits of lower loss, higher power-handling, and higher IP3, especially at higher frequencies (>10 GHz). MEMS based varactors can also be used for this purpose. They use different bias voltages to vary the electrostatic force between two parallel plates of the varactor and hence change its capacitance value. They show lower Q than tunable dielectric capacitors, and have worse power handling, but can be used successfully for some applications.

Tunable devices, such as, filters phase shifters, delay lines, VCOs, antenna and PA tuners, have been developed for microwave radio applications. They may be tuned electronically using a tunable dielectric capacitor. Tunable RF components offer service providers flexibility and scalability. A single tunable device solution enables radio manufacturers to replace several fixed components needed to perform the same function. This versatility provides front end RF tunability in real time applications and decreases deployment and maintenance costs through software control and reduced component count.

The trend towards the supply of RF modules rather than discrete components is clear for Handset Manufacturers, with the size and cost reduction being an important factor. Typically the RF stage is spread over the circuit board necessitating extensive assembly by the OEM. These assembly costs combined with inventory and risks, design time and expense are frustrating factors for the OEM. Consequently, the Handset Manufacturers are seeking greater levels of integration in the RF stage and are seeking to combine passives and ICs into a single package. In addition, the RF subsystem of a modem multi-mode, multi-band mobile phone represents great complexity with an extremely high part count. High-frequency chip packages have been described. For example, Patent Application Publication No. 20030062541, entitled, “High-frequency chip packages” describes a packaged semiconductor chip having a large thermal conductor which can be solder-bonded to a circuit board so as to provide enhanced thermal conductivity to the circuit board and electromagnetic shielding and a conductive enclosure which partially or completely surrounds the packaged chip to provide additional heat dissipation and shielding.

Thus, there is a strong need for high-frequency chip packaging with greater levels of integration in the RF stage and are capable of combining passives and ICs into a single package.

### SUMMARY OF THE INVENTION

The present invention provides a packaged semiconductor chip comprising a first semiconductor chip 120 having an upwardly-facing front face 145, a downwardly-facing rear face 155, edges 160 bounding the faces and contacts 150 exposed at the front surface 145, the first semiconductor chip 120 including active components. The packaged semiconductor chip 100 further includes a connecting element 105 which may include passive components, the connecting element 105 may be electrically connected to at least some of the contacts 150, the connecting element 105 may overly the front face 145 of the first chip 120 and project outwardly beyond the edges 160 of the first chip 120.

The packaged semiconductor chip 100 also comprises a chip carrier 130 disposed below the rear surface 155 of the first chip 120, the chip carrier 130 having a bottom surface 132 facing downwardly away from the chip 120 and having a plurality of terminals 134 and 136 exposed at the bottom surface, at least some of the terminals 134 and 136 being electrically connected to at least some of the contacts 150 of the first chip through the connecting element. A voltage tunable capacitor 125 may be electrically connected to the connecting element and the first chip 120 may include active semiconductor components.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates the High Frequency Chip Packages incorporating voltage tunable varactors of the present invention;

FIG. 2 is an Isometric view of a voltage tunable oscillator (VTO) using the High Frequency Chip Packages of the present invention;

FIG. 3 is a block diagram of a synthesizer incorporating Parascan® varactors that can be incorporated into the High Frequency Chip Packages of the present invention; and

FIG. 4 depicts a bottom plane that may be used for filter integrated into the High Frequency Chip Packages of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION OF THE INVENTION

The present invention's electronically tunable RF devices reduces complex chip packaging by replacing multiple components with a single tunable device that can tune its frequency, phase, time delay, etc., over multiple bands. Ultimately, several of these tunable devices can be integrated into a larger module to produce even further reduction in size and costs.

If these tunable devices and modules that already help Handset Manufacturers to benefit from size and part count reduction, as well as, cost reduction, are made in small chip package, the benefit will be twofold. A tunable device made in miniature package is perhaps one of the most desired components in smart radios. Although the present invention is not limited in this respect.

Inherent in every tunable device is the ability to rapidly tune the response using high-impedance control lines. Parascan® materials technology enables these tuning properties, as well as, high Q values, low losses and extremely high IP3 characteristics, even at high frequencies. MEM based varactors can also be used for this purpose. They use different bias voltages to vary the electrostatic force between two parallel plates of the varactor and hence change its capacitance value. They show lower Q than dielectric varactors, and have worse power handling, but can be used successfully for some applications. Also, diode varactors could be used to make tunable devices, although with worse performance than dielectric varactors.

A packaged miniaturized chip that can include both passive and active components with good thermal conductivity, surface mountable, and with electromagnetic shielding can be combined with Parascan tunable technology and produce the ideal platform for system on chip, or miniature tunable RF Front End Module.

Specifically, the miniaturized package chip technology is capable of producing high Q passive RF components, such as inductor, and capacitors, as well as resistors. These basic elements together with other components like via holes, SAW devices, etc., may be used to design most passive RF devices, such as, filters, delay lines, etc. Also, the small packaged unit may include active semiconductor chips to produce devices like amplifiers, VCOs, switches, etc. All of these passive and active devices can be used as single chip, or as part of a larger module.

The RF subsystem of a modern multi-mode, multi-band mobile phone represents tremendous complexity with an extremely high part count and an area wherein the present invention enhances the state of the art.

One current chip packaging technique is illustrated in Patent Application Publication No. 20030062541, entitled, “High-frequency chip packages” which describes a packaged semiconductor chip having a large thermal conductor which can be solder-bonded to a circuit board so as to provide enhanced thermal conductivity to the circuit board and electromagnetic shielding and a conductive enclosure which partially or completely surrounds the packaged chip to provide additional heat dissipation and shielding. The packaged unit may include both an active semiconductor chip and a passive element, desirably in the form of a chip, which includes resistors and capacitors. Inductors may be provided in whole or in part on the chip carrier. A module includes two circuits and an enclosure with a medial wall between the circuits to provide electromagnetic shielding between the circuits. This patent application is incorporated herein by reference. However, this chip packaging technique utilizes a dielectric material that does not contain tunable material and therefore has limitations.

The assignee of the present invention has produced electronically tunable RF devices that reduce such complexity by replacing multiple components with a single tunable device that can tune its frequency, phase, time delay, etc., over multiple bands. Ultimately, several of these tunable devices can be integrated into a larger module to produce even further reduction in size and costs.

The term Parascan® as used herein is a trademarked word indicating a tunable dielectric material developed by the assignee of the present invention. Parascan® tunable dielectric materials have been described in several patents. Barium strontium titanate (BaTiO₃—SrTiO₃), also referred to as BSTO, is used for its high dielectric constant (200-6,000) and large change in dielectric constant with applied voltage (25-75 percent with a field of 2 Volts/micron). Tunable dielectric materials including barium strontium titanate are disclosed in U.S. Pat. No. 5,312,790 to Sengupta, et al. entitled “Ceramic Ferroelectric Material”; U.S. Pat. No. 5,427,988 by Sengupta, et al. entitled “Ceramic Ferroelectric Composite Material-BSTO—MgO”; U.S. Pat. No. 5,486,491 to Sengupta, et al. entitled “Ceramic Ferroelectric Composite Material —BSTO—ZrO₂”; U.S. Pat. No. 5,635,434 by Sengupta, et al. entitled “Ceramic Ferroelectric Composite Material-BSTO-Magnesium Based Compound”; U.S. Pat. No. 5,830,591 by Sengupta, et al. entitled “Multilayered Ferroelectric Composite Waveguides”; U.S. Pat. No. 5,846,893 by Sengupta, et al. entitled “Thin Film Ferroelectric Composites and Method of Making”; U.S. Pat. No. 5,766,697 by Sengupta, et al. entitled “Method of Making Thin Film Composites”; U.S. Pat. No. 5,693,429 by Sengupta, et al. entitled “Electronically Graded Multilayer Ferroelectric Composites”; U.S. Pat. No. 5,635,433 by Sengupta entitled “Ceramic Ferroelectric Composite Material BSTO-ZnO”; U.S. Pat. No. 6,074,971 by Chiu et al. entitled “Ceramic Ferroelectric Composite Materials with Enhanced Electronic Properties BSTO-Mg Based Compound-Rare Earth Oxide”. These patents are incorporated herein by reference. The materials shown in these patents, especially BSTO-MgO composites, show low dielectric loss and high tunability. Tunability is defined as the fractional change in the dielectric constant with applied voltage.

Barium strontium titanate of the formula BaₓSr₁₋ₓTiO₃ is a preferred electronically tunable dielectric material due to its favorable tuning characteristics, low Curie temperatures and low microwave loss properties. In the formula BaₓSr₁₋ₓTiO₃, x can be any value from 0 to 1, preferably from about 0.15 to about 0.6. More preferably, x is from 0.3 to 0.6.

Other electronically tunable dielectric materials may be used partially or entirely in place of barium strontium titanate. An example is BaₓCa₁₋ₓTiO₃, where x is in a range from about 0.2 to about 0.8, preferably from about 0.4 to about 0.6. Additional electronically tunable ferroelectrics include PbₓZr₁₋ₓTiO₃ (PZT) where x ranges from about 0.0 to about 1.0, PbₓZr₁₋ₓSrTiO₃ where x ranges from about 0.05 to about 0.4, KTa₂Nb₁₋ₓO₃ where x ranges from about 0.0 to about 1.0, lead lanthanum zirconium titanate (PLZT), PbTiO₃, BaCaZrTiO₃, NaNO₃, KNbO₃, LiNbO₃, LiTaO₃, PbNb₂O₆, PbTa₂O₆, KSr(NbO₃) and NaBa₂(NbO₃)₅KH₂PO₄, and mixtures and compositions thereof. Also, these materials can be combined with low loss dielectric materials, such as magnesium oxide (MgO), aluminum oxide (Al₂O₃), and zirconium oxide (ZrO₂), and/or with additional doping elements, such as manganese (MN), iron (Fe), and tungsten (W), or with other alkali earth metal oxides (i.e. calcium oxide, etc.), transition metal oxides, silicates, niobates, tantalates, aluminates, zirconnates, and titanates to further reduce the dielectric loss.

In addition, the following U.S. Patent Applications, assigned to the assignee of this application, disclose additional examples of tunable dielectric materials: U.S. application Ser. No. 09/594,837 filed Jun. 15, 2000, entitled “Electronically Tunable Ceramic Materials Including Tunable Dielectric and Metal Silicate Phases”; U.S. application Ser. No. 09/768,690 filed Jan. 24, 2001, entitled “Electronically Tunable, Low-Loss Ceramic Materials Including a Tunable Dielectric Phase and Multiple Metal Oxide Phases”; U.S. application Ser. No. 09/882,605 filed Jun. 15, 2001, entitled “Electronically Tunable Dielectric Composite Thick Films And Methods Of Making Same”; U.S. application Ser. No. 09/834,327 filed Apr. 13, 2001, entitled “Strain-Relieved Tunable Dielectric Thin Films”; and U.S. Provisional Application Ser. No. 60/295,046 filed Jun. 1, 2001 entitled “Tunable Dielectric Compositions Including Low Loss Glass Frits”. These patent applications are incorporated herein by reference.

The tunable dielectric materials can also be combined with one or more non-tunable dielectric materials. The non-tunable phase(s) may include MgO, MgAl₂O₄, MgTiO₃, Mg₂SiO₄, CaSiO₃, MgSrZrTiO₆, CaTiO₃, Al₂O₃, SiO₂ and/or other metal silicates such as BaSiO₃ and SrSiO₃. The non-tunable dielectric phases may be any combination of the above, e.g., MgO combined with MgTiO₃, MgO combined with MgSrZrTiO₆, MgO combined with Mg₂SiO₄, MgO combined with Mg₂SiO₄, Mg₂SiO₄ combined with CaTiO₃ and the like.

Additional minor additives in amounts of from about 0.1 to about 5 weight percent can be added to the composites to additionally improve the electronic properties of the films. These minor additives include oxides such as zirconnates, tannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆ and Ta₂O₃.

Thick films of tunable dielectric composites can comprise Ba₁₋ₓSrₓTiO₃, where x is from 0.3 to 0.7 in combination with at least one non-tunable dielectric phase selected from MgO, MgTiO₃, MgZrO₃, MgSrZrTiO₆, Mg₂SiO₄, CaSiO₃, MgAl₂O₄, CaTiO₃, Al₂O₃, SiO₂, BaSiO₃ and SrSiO₃. These compositions can be BSTO and one of these components, or two or more of these components in quantities from 0.25 weight percent to 80 weight percent with BSTO weight ratios of 99.75 weight percent to 20 weight percent.

The electronically tunable materials can also include at least one metal silicate phase. The metal silicates may include metals from Group 2A of the Periodic Table, i.e., Be, Mg, Ca, Sr, Ba and Ra, preferably Mg, Ca, Sr and Ba. Preferred metal silicates include Mg₂SiO₄, CaSiO₃, BaSiO₃ and SrSiO₃. In addition to Group 2A metals, the present metal silicates may include metals from Group 1A, i.e., Li, Na, K, Rb, Cs and Fr, preferably Li, Na and K. For example, such metal silicates may include sodium silicates such as Na₂SiO₃ and NaSiO₃-5H₂O, and lithium-containing silicates such as LiAlSiO₄, Li₂SiO₃ and Li₄SiO₄. Metals from Groups 3A, 4A and some transition metals of the Periodic Table may also be suitable constituents of the metal silicate phase. Additional metal silicates may include Al₂Si₂O₇, ZrSiO₄, KalSi₃O₈, NaAlSi₃O₈, CaAl₂Si₂O₈, CaMgSi₂O₆, BaTiSi₃O₉ and Zn₂SiO₄. The above tunable materials can be tuned at room temperature by controlling an electric field that is applied across the materials.

In addition to the electronically tunable dielectric phase, the electronically tunable materials can include at least two additional metal oxide phases. The additional metal oxides may include metals from Group 2A of the Periodic Table, i.e., Mg, Ca, Sr, Ba, Be and Ra, preferably Mg, Ca, Sr and Ba. The additional metal oxides may also include metals from Group 1A, i.e., Li, Na, K, Rb, Cs and Fr, preferably Li, Na and K. Metals from other Groups of the Periodic Table may also be suitable constituents of the metal oxide phases. For example, refractory metals such as Ti, V, Cr, Mn, Zr, Nb, Mo, Hf, Ta and W may be used. Furthermore, metals such as Al, Si, Sn, Pb and Bi may be used. In addition, the metal oxide phases may comprise rare earth metals such as Sc, Y, La, Ce, Pr, Nd and the like.

The additional metal oxides may include, for example, zirconnates, silicates, titanates, aluminates, stannates, niobates, tantalates and rare earth oxides. Preferred additional metal oxides include Mg₂SiO₄, MgO, CaTiO₃, MgZrSrTiO₆, MgTiO₃, MgAl₂O₄, WO₃, SnTiO₄, ZrTiO₄, CaSiO₃, CaSnO₃, CaWO₄, CaZrO₃, MgTa₂O₆, MgZrO₃, MnO₂, PbO, Bi₂O₃ and La₂O₃. Particularly preferred additional metal oxides include Mg₂SiO₄, MgO, CaTiO₃, MgZrSrTiO₆, MgTiO₃, MgAl₂O₄, MgTa₂O₆ and MgZrO₃.

The additional metal oxide phases are typically present in total amounts of from about 1 to about 80 weight percent of the material, preferably from about 3 to about 65 weight percent, and more preferably from about 5 to about 60 weight percent. In one preferred embodiment, the additional metal oxides comprise from about 10 to about 50 total weight percent of the material. The individual amount of each additional metal oxide may be adjusted to provide the desired properties. Where two additional metal oxides are used, their weight ratios may vary, for example, from about 1:100 to about 100:1, typically from about 1:10 to about 10:1 or from about 1:5 to about 5:1. Although metal oxides in total amounts of from 1 to 80 weight percent are typically used, smaller additive amounts of from 0.01 to 1 weight percent may be used for some applications.

The additional metal oxide phases can include at least two Mg-containing compounds. In addition to the multiple Mg-containing compounds, the material may optionally include Mg-free compounds, for example, oxides of metals selected from Si, Ca, Zr, Ti, Al and/or rare earths.

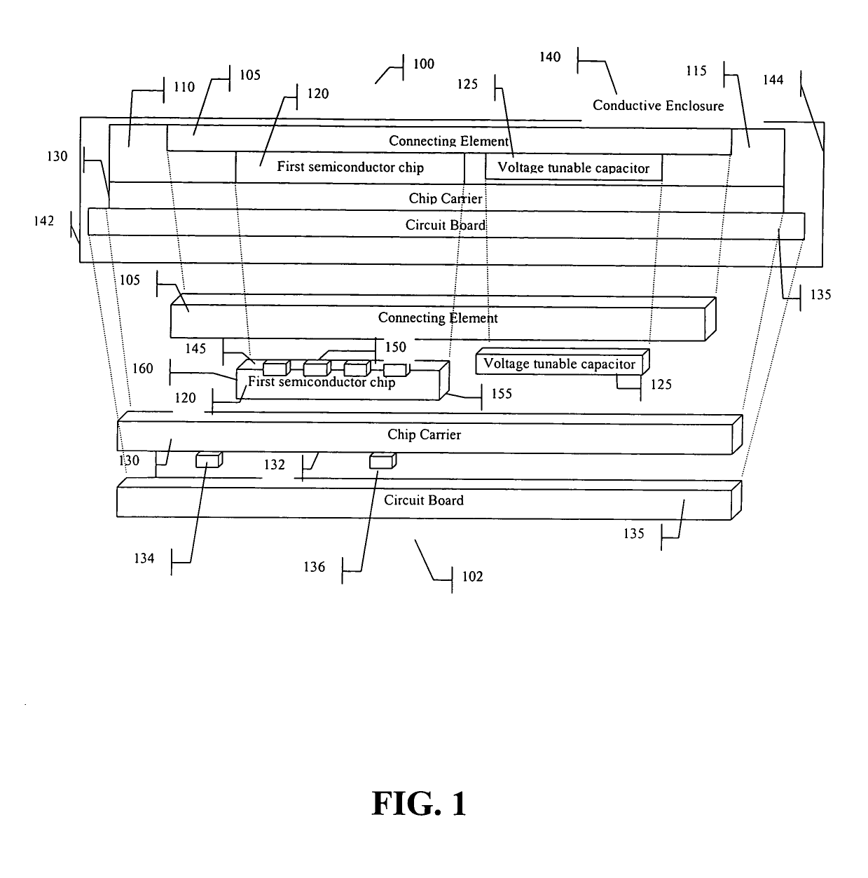

Turning now to the figures, FIG. 1, shown generally at 100, and blown up and three dimensional at 102, illustrates a packaged semiconductor chip comprising a first semiconductor chip 120 having an upwardly-facing front face 145, a downwardly-facing rear face 155, edges 160 bounding the faces and contacts 150 exposed at the front surface 145, the first semiconductor chip 120 including active components. The packaged semiconductor chip 100 further includes a connecting element 105 which may include passive components, the connecting element 105 may be electrically connected to at least some of the contacts 150, the connecting element 105 overlying the front face 145 of the first chip 120 and projecting outwardly beyond the edges 160 of the first chip 120.

The packaged semiconductor chip 100 also comprises a chip carrier 130 disposed below the rear surface 155 of the first chip 120, the chip carrier 130 having a bottom surface 132 facing downwardly away from the chip 120 and having a plurality of terminals 134 and 136 exposed at the bottom surface, at least some of the terminals 134 and 136 being electrically connected to at least some of the contacts 150 of the first chip through the connecting element. A voltage tunable capacitor 125 may be electrically connected to the connecting element and the first chip 120 may include active semiconductor components.

The passive components in the connection element 105 may include at least one passive component selected from the group consisting of resistors and capacitors. Further, at least one inductor may be formed at least in part on the chip carrier 130.

The connecting elements may include an overlying electrically conductive enclosure 140 and the enclosure may be a hollow can shaped structure having a rear wall (not shown) overlying the second semiconductor chip 120 and having side walls 142 and 144 extending downwardly to the vicinity of the chip carrier 130. The chip carrier 130 may be a sheet-like element having thickness in the vertical direction less than about 150 microns and the chip carrier 130 may include a thermal conductor underlying at least a major portion of the rear surface 155 of the first chip, the thermal conductor may be in thermal communication with the first chip 120, the thermal conductor may be exposed at the bottom surface 132 of the chip carrier. The thermal conductor and the terminals may be adapted for surface mounting to a circuit board 135 and the chip carrier may include peripheral portions extending outwardly beyond the edges of the first semiconductor chip 120, all of the terminals being disposed in the peripheral portions.

Although the present invention is not limited in this respect, the connecting element 105 may be a second chip and the first semiconductor chip 120 and the second semiconductor chip (which may be the connecting element 105) may include different semiconductors. This second semiconductor chip may have minimum feature size larger than the minimum feature size of the first semiconductor chip 120. Further, the voltage tunable capacitor may be selected from the group based upon ferro-electric materials and wherein the ferro-electric materials may be Parascan® dielectric materials.

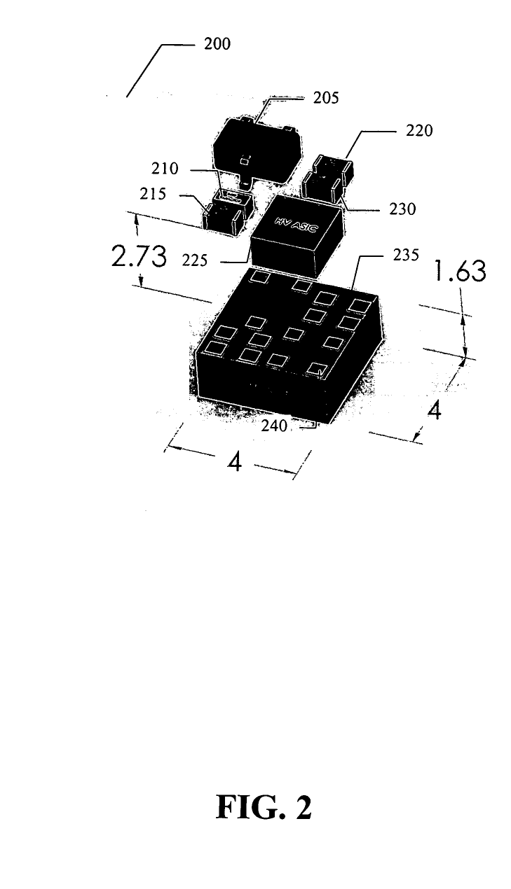

The small packaged unit of the present invention can include active semiconductor chips to produce devices like amplifiers, VCOs and switches. Although examples of such devices are illustrated below, it is understood that the present invention is not limited to these devices. All of these passive and active devices can be used as single chip, or as part of a larger module Turning now to FIG. 2, shown generally at 200, the packaged semiconductor chip of the present invention may have the functionality of a Voltage Tunable Oscillator (VTO). The VTO may consist of an LTCC multiplayer substrate 235 with solder-able pads 240 on the top to accommodate surface mount components 205, 210, 215, 220, 225 and 230 and solder-able tabs (not shown) on the bottom for connection to the user's motherboard (not shown). The components may include HV ASIC 225 and RF transistor 225. Although the present invention is not limited in this respect. The assembly procedure may include applying solder paste, pick and placing surface mount components, re-flow soldering, applying molding, cure molding, perform power and frequency GO/NO-GO testing and finally packaging in tape & reel. In one embodiment there is no metal lid, nor any covering except the molding. The molding should protect against handling by the user and against environmental conditions. Further, no tuning may be required with the possibility of only an automated GO/NO-GO test during production.

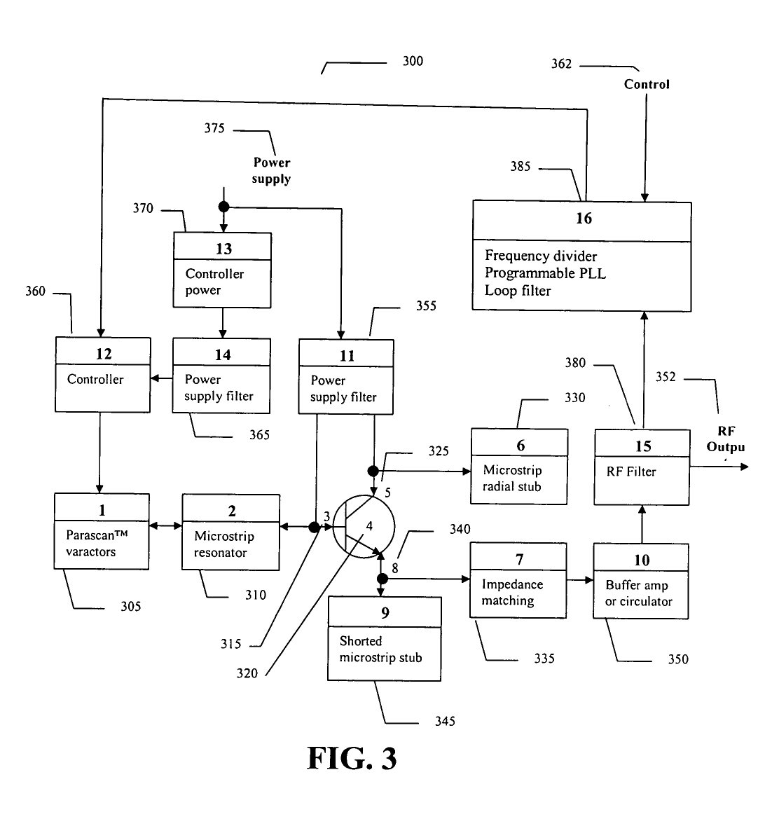

FIG. 3 at 300 illustrates the packaged semiconductor chip of the present invention that may have the functionality of a synthesizer using a voltage controlled oscillator (VCO). FIG. 3 illustrates a functional block diagram of a VCO incorporating a Parascan® varactor which can be packaged using the packaging technique of the present invention. Parascan® varactors 305 are used in a microstrip resonator 310 providing a high resonator Q-factor. Negligible noise is generated by the Parascan® varactors 305. The resonator 310 is coupled into the base circuit 315 of a Si-bipolar transistor 320, thus providing a low flicker noise corner frequency.

The collector 325 of the Si-bipolar transistor 320 is terminated in a radial microstrip stub330 providing an RF short at the frequency of oscillation, thus ensuring the conditions under which oscillation can exist.

The output is coupled via an impedance matching circuit 335 s buffer amplifier or a circulator 350 and an RF Filter 380 to the emitter 340 of the Si-bipolar transistor 320. RF Filter 380 is added in the output circuit to prevent harmonics of the clock and reference frequency from exiting the synthesizer. The emitter 340 of the Si-bipolar transistor 320 is further terminated into a short-circuited microstrip stub 345, preventing lower modes of oscillation to exist. Further, the output of RF filter 380 is input to state-of-the-art frequency divider, programmable phase locked loop and loop filter 385.

The frequency divider, programmable phase locked loop and loop filter 385 provides fast switching, low spurious, and low close-in phase noise. Control 362 is also provided to frequency divider, programmable phase locked loop and loop filter 385 as shown at 362. The output of frequency divider programmable PLL loop filter 385 is provided to controller 360.

Again, a buffer amplifier 350 may be added in the output circuit to amplify the output power 352 where needed. Filtering, via power supply filter 355, the power supply input and regulating the supply voltage essentially eliminate the pushing effect. Control 362 is provided by a simple one-transistor controller 360 which scales the user-selected control voltage range to the levels required by the Parascan® varactors 305. The controller 360 has a user-specified frequency response, thus aiding integration with phase-locked loop synthesizers.

A power supply 375 provides power to an integral switch-mode power supply 370 which generates the rail voltage for the controller 360. Filtering 365 provide sufficient rejection of switching noise prior to reaching controller 360.

In addition to providing packaging for a synthesizer, the present packaged semiconductor chip has the functionality of a tunable RF front end. The inventor of the present invention has developed an Electronically Tunable RF Front End Module described in detail in U.S. patent application Ser. No. 10/748,709, provisionally filed on Feb. 5, 2003 and non-provisional filed on Dec. 30, 2003 and entitled “Electronically Tunable RF Front End Module” and assigned to the assignee of the present invention. This patent application is incorporated herein by reference. By using the packaged semiconductor chip technology of the present invention, with the Electronically Tunable RF Front End Module of the patent application incorporated in by reference, the present packaged semiconductor chip may have the functionality of a tunable RF front end.

U.S. patent application Ser. No. 10/757,314 entitled, “LTCC Based Electronically Tunable Multilayer Microstrip-Stripline Combline Filter” provisionally filed Feb. 5, 2003 and non-provisinally filed Jan. 14, 2004 describes a tunable multilayer microstrip-stripline combline filter. This patent application is incorporated in by reference. The filter needs several layers of dielectric material or low-temperature-cofired-ceramic (LTCC) tape. In a particular example, a three-pole filter is realized using LTCC tapes. This filter uses total of nine tape layers and is set forth in greater detail in the aforementioned patent application.

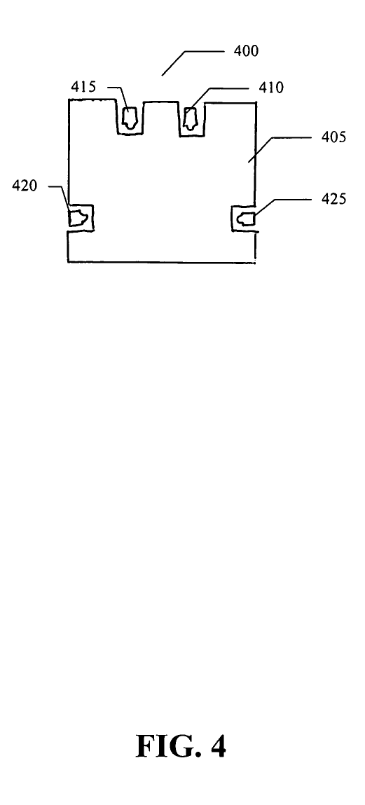

To make the tunable filter surface mountable in the packaging of a semiconductor chip of the present invention, the RF input/output lines and the DC biasing lines are taken to the bottom plane (only the bottom plane is depicted herein for reference to use with the present invention and all planes are more specifically set forth in the US patent application set forth above and incorporated herein by reference). The bottom plane is shown in FIG. 4 at 400 wherein the plane is set forth at 405 and with input/output lines shown at 410, 415, 420 and 425.

The present invention also provides for a method of packaging a semiconductor chip, comprising: providing a first semiconductor chip 120 having an upwardly-facing front face 145, a downwardly-facing rear face 155, edges 165 bounding the faces and contacts 150 exposed at the front surface 145, the first semiconductor chip 120 may include active components; connecting electrically by a connecting element 105 at least some of the contacts 150, the connecting element 105 may include passive components and overlying the front face 145 of the first chip 120 and projecting outwardly beyond the edges of the first chip 120; disposing a chip carrier 130 below the rear surface 155 of the first chip 120, the chip carrier 130 having a bottom surface 132 facing downwardly away from the first semiconductor chip 120 and having a plurality of terminals 134 and 136 exposed at the bottom surface 132, at least some of the terminals 132 and 136 being electrically connected to at least some of the contacts 150 of the first semiconductor chip 120 through the connecting element 140; and connecting electrically a voltage tunable capacitor to the connecting element.

While the present invention has been described in terms of what are at present believed to be its preferred embodiments, those skilled in the art will recognize that various modifications to the disclose embodiments can be made without departing from the scope of the invention as defined by the following claims.

1. A packaged semiconductor chip comprising:
a first semiconductor chip having an upwardly-facing front face, a downwardly-facing rear face, edges bounding said faces and contacts exposed at said front surface, said first semiconductor chip including active components;
a connecting element including passive components, said connecting element being electrically connected to at least some of said contacts, said connecting element overlying the front face of said first chip and projecting outwardly beyond said edges of said first chip;
a chip carrier disposed below said rear surface of said first chip, said chip carrier having a bottom surface facing downwardly away from said chip and having a plurality of terminals exposed at said bottom surface, at least some of said terminals being electrically connected to at least some of said contacts of said first chip through said connecting element; and
a voltage tunable capacitor, said voltage tunable capacitor being electrically connected to said connecting element.

2. The packaged semiconductor chip of claim 1, wherein said first chip includes active semiconductor components.

3. The packaged semiconductor chip of claim 1, wherein said passive components in said connecting element include at least one passive component selected from the group consisting of resistors and capacitors.

4. The packaged semiconductor chip of claim 1, further comprising at least one inductor formed at least in part on said chip carrier.

5. The packaged semiconductor chip of claim 1, further comprising an electrically conductive enclosure element overlying said connecting element.

6. The packaged semiconductor chip of claim 1, wherein said enclosure element is a hollow can-shaped enclosure having a rear wall overlying said second semiconductor chip and having side walls extending downwardly to the vicinity of said chip carrier.

7. The packaged semiconductor chip of claim 1, wherein said chip carrier is a sheet-like element having thickness in the vertical direction less than about 150 microns.

8. The packaged semiconductor chip of claim 1, wherein said chip carrier includes a thermal conductor underlying at least a major portion of said rear surface of said first chip, said thermal conductor being in thermal communication with said first chip, said thermal conductor being exposed at said bottom surface of said chip carrier.

9. The packaged semiconductor chip of claim 1, wherein said thermal conductor and said terminals are adapted for surface mounting to a circuit board.

10. The packaged semiconductor chip of claim 1, wherein said chip carrier includes peripheral portions extending outwardly beyond the edges of said first semiconductor chip, all of said terminals being disposed in said peripheral portions.

11. The packaged semiconductor chip of claim 1, wherein said connecting element is a second chip.

12. The packaged semiconductor chip of claim 1, wherein said first semiconductor chip and said second semiconductor chip include different semiconductors.

13. The packaged semiconductor chip of claim 1, wherein said second semiconductor chip has minimum feature size larger than the minimum feature size of said first semiconductor chip.

14. The packaged semiconductor chip of claim 1, wherein said voltage tunable capacitor is selected from the group based upon ferro-electric materials.

15. The packaged semiconductor chip of claim 14, wherein said ferro-electric materials are Parascan® dielectric materials.

16. The packaged semiconductor chip of claim 1, wherein said packaged semiconductor chip has the functionality of a Voltage Tunable Oscillator (VTO).

17. The packaged semiconductor chip of claim 1, wherein said packaged semiconductor chip has the functionality of a synthesizer.

18. The packaged semiconductor chip of claim 1, wherein said packaged semiconductor chip has the functionality of a tunable RF front end.

19. A method of packaging a semiconductor chip, comprising:
providing a first semiconductor chip having an upwardly-facing front face, a downwardly-facing rear face, edges bounding said faces and contacts exposed at said front surface, said first semiconductor chip including active components;
connecting electrically by a connecting element at least some of said contacts, said connecting element including passive components and overlying the front face of said first chip and projecting outwardly beyond said edges of said first chip;
disposing a chip carrier below said rear surface of said first chip, said chip carrier having a bottom surface facing downwardly away from said chip and having a plurality of terminals exposed at said bottom surface, at least some of said terminals being electrically connected to at least some of said contacts of said first chip through said connecting element; and
connecting electrically a voltage tunable capacitor to the said connecting element.

20. The method of claim 19, wherein said first chip includes active semiconductor components.

21. The method of claim 19, wherein said passive components in said connecting element include at least one passive component selected from the group consisting of resistors and capacitors.

22. The method of claim 19, further comprising providing at least one inductor formed at least in part on said chip carrier.

23. The method of claim 19, further comprising providing an electrically conductive enclosure element overlying said connecting element.
